(19) United States
(12) Patent Application Publication
(10) Pub. No.: US 2026/0107994 A1
(43) Pub. Date: Apr. 23, 2026

(54) HEAT-RESISTANT PROTECTIVE SHIELD

(71) Applicant: TAROKO INTERNATIONAL CO., LTD., Tainan City (TW)

(72) Inventor: MING-YANG WANG LEE, Tainan City (TW)

(21) Appl. No.: 18/924,847

(22) Filed: Oct. 23, 2024

(51) Int. Cl. A41D 13/11; C23C 14/06; C23C 14/20

(52) U.S. Cl. CPC A41D 13/1184; C23C 14/0641; C23C 14/205

(57) ABSTRACT

Provided is a heat-resistant protective shield, which sequentially comprises a polycarbonate molded object, a silicon dioxide hard coating, a copper-zinc alloy layer and a dielectric layer, wherein the dielectric layer comprises titanium nitride, zirconium nitride, zirconium dioxide or a combination thereof; the copper-zinc alloy layer has a thickness of 0.2 μm to 3.0 μm, the dielectric layer has a thickness of 10 nm to 999 nm, and the copper-zinc alloy layer and the dielectric layer have a thickness ratio of 1:1 to 100:1. The heat-resistant protective shield has good heat resistance, visible light transmittance and infrared light transmittance along with the advantage of cost reduction, and it also has change rates of the visible light transmittance and the infrared light transmittance of less than or equal to 100% after being heat treated at a temperature of 60° C. and a relative humidity of 90RH % for 200 hours, indicating a relatively good stability and being suitable for long term use.

### BACKGROUND OF THE INVENTION

### 1. Field of the Invention

The present invention relates to a heat-resistant protective shield, especially a heat-resistant protective shield suitable for special working environments.

### 2. Description of the Prior Arts

The special working environments, which involve the processes of welding, grinding, cutting and construction, etc., may result in high exposure to hazardous factors, such as smoke, heat, and infrared light, etc. Therefore, the operators need to wear protective masks to protect their faces and eyes during the operation to avoid damages resulting from said hazardous factors.

In order to guarantee a good visibility of the operators in said special working environments, the protective mask shall have a certain degree of light transmittance to achieve the required visibility, thereby allowing operation in a high-temperature working environment. Further, if the protective mask does not have sufficient heat-resistant capacity, its surface may have the problems of oxidation, melting and blistering resulting from heat in said high-temperature working environment, thereby losing protective capacity. Further, high exposure to infrared light may cause the symptoms of eye burning, or even result in retinal burns, not to mention that a long-term exposure may reduce the elasticity of the crystalline lens and result in decreased vision.

A currently available protective mask usually comprises a plastic body plated with a pure gold layer, which is expensive with limited popularization. Hence, there is an urgent need to develop a material with both advantages of low cost and required protective capacity to improve the quality of conventional protective masks.

### SUMMARY OF THE INVENTION

In view of the aforementioned disadvantages of the prior art, one objective of the present invention is to provide a heat-resistant protective shield with the advantages of low cost, good heat resistance, good infrared light shielding capacity and good visibility.

Another objective of the present invention is to improve the stability of the heat-resistant protective shield, thereby maintaining good infrared light shielding capacity and good visibility for a long term use in a high-temperature working environment.

To achieve said objectives, the present invention provides a heat-resistant protective shield, comprising:
a polycarbonate molded object;
a silicon dioxide hard coating, located on a surface of the polycarbonate molded object;
a copper-zinc alloy layer, located on the silicon dioxide hard coating, the copper-zinc alloy layer having copper in an amount of greater than 0% to less than 100%, and zinc in an amount of less than 100% to greater than 0%; and
a dielectric layer, located on the copper-zinc alloy layer and comprising titanium nitride (TiN), zirconium nitride (ZrN), zirconium dioxide (ZrO₂) or a combination thereof;
wherein the copper-zinc alloy layer has a thickness of 0.2 micrometers (μm) to 3.0 μm, the dielectric layer has a thickness of 10 nanometers (nm) to 999 nm, and the copper-zinc alloy layer and the dielectric layer have a thickness ratio of 1:1 to 100:1.

In a specific example of the present invention, the polycarbonate molded object is a lens or a face shield. In the specific example of the present invention, the lens or the face shield can be obtained by an injection molding method; or, an object to be plated is firstly obtained by an extrusion molding, blow molding, casting, or thermoforming method, and then processed to obtain the lens or the face shield. In the present invention, the polycarbonate molded object serves as a base.

12 In a specific example of the present invention, the material of the polycarbonate molded object is an ordinary polycarbonate, or a commercial polycarbonate with a low phase difference.

In a specific example of the present invention, the material of the polycarbonate molded object has a weight average molecular weight (Mw) of 20000 to 150000, 30000 to 140000, 40000 to 130000, 50000 to 120000, 60000 to 110000, 70000 to 100000, or 80000 to 90000.

In a specific example of the present invention, the material of the polycarbonate molded object has a melt flow index (MI), determined with a load of 2.16 kilograms (kg) at 190° C., of 1 gram per 10 minutes (g/10 min) to 30 g/10 min, 5 g/10 min to 25 g/10 min, 10 g/10 min to 20 g/10 min, or 15 g/10 min to 20 g/10 min.

In a specific example of the present invention, the material of the polycarbonate molded object has a glass transition temperature (Tg) of 100° C. to 180° C., 110° C. to 170° C., 120° C. to 160° C., 130° C. to 150° C., or 130° C. to 140° C.

In a specific example of the present invention, the polycarbonate molded object has a thickness of 0.5 millimeters (mm) to 5.0 mm, 1.0 mm to 4.0 mm, 1.5 mm to 3.5 mm, 2.0 mm to 3.0 mm, or 2.0 mm to 2.5 mm.

In a specific example of the present invention, the material of the silicon dioxide hard coating comprises silica (SiO₂) microparticles, a curing polymer and an oligomer. In the present invention, the silicon dioxide hard coating can strengthen the surface hardness of the heat-resistant protective shield.

In a specific example of the present invention, the material of the silicon dioxide hard coating is applied to a surface of the polycarbonate molded object by spray coating or sprinkle coating.

In a specific example of the present invention, the curing polymer of the silicon dioxide hard coating can be a room temperature curing polymer, a thermosetting polymer and/or an ultraviolet (UV) curing polymer. In a specific example of the present invention, the curing polymer of the material of the silicon dioxide hard coating is a room temperature curing polymer, that is, the material of the silicon dioxide hard coating is applied to a surface of the polycarbonate molded object and then cured at room temperature to obtain the silicon dioxide hard coating. In a specific example of the present invention, the curing polymer of the material of the silicon dioxide hard coating is a thermosetting polymer, that is, the material of the silicon dioxide hard coating is applied to a surface of the polycarbonate molded object and then cured with heat to obtain the silicon dioxide hard coating. In a specific example of the present invention, the curing polymer of the material of the silicon dioxide hard coating is a UV curing polymer, that is, the material of the silicon dioxide hard coating is applied to a surface of the polycarbonate molded object and then cured by UV light to obtain the silicon dioxide hard coating.

In a specific example of the present invention, the material of the silicon dioxide hard coating has a solid content of 1% to 40%, or 5% to 35%, or 10% to 30%, or 15% to 25%, or 20% to 25%.

In a specific example of the present invention, the material of the silicon dioxide hard coating has a coating thickness (wet film thickness) of 1 μm to 99 μm, or 10 μm to 90 μm, or 20 μm to 80 μm, or 30 μm to 70 μm, or 40 μm to 60 μm, or 50 μm to 60 μm. In a specific example of the present invention, the silicon dioxide hard coating has a thickness (after curing) of 1 μm to 30 μm, or 5 μm to 25 μm, or 10 μm to 20 μm, or 15 μm to 20 μm.

In a specific example of the present invention, the copper-zinc alloy layer is plated on the silicon dioxide hard coating. In a specific example of the present invention, the material of the copper-zinc alloy layer is plated on the silicon dioxide hard coating by a vacuum sputtering method. In the present invention, the copper-zinc alloy layer has thermal conductivity and shielding capacity.

In a specific example of the present invention, the cooper of the copper-zinc alloy layer is in an amount of greater than or equal to 5% to less than or equal to 95%, and the zinc of the copper-zinc alloy layer is in an amount of less than or equal to 95% to greater than or equal to 5%; or copper in an amount of greater than or equal to 10% to less than or equal to 90%, and the zinc of the copper-zinc alloy layer is in an amount of less than or equal to 90% to greater than or equal to 10%; or copper in an amount of greater than or equal to 15% to less than or equal to 85%, and the zinc of the copper-zinc alloy layer is in an amount of less than or equal to 85% to greater than or equal to 15%; or copper in an amount of greater than or equal to 20% to less than or equal to 80%, and the zinc of the copper-zinc alloy layer is in an amount of less than or equal to 80% to greater than or equal to 20%; or copper in an amount of greater than or equal to 25% to less than or equal to 75%, and the zinc of the copper-zinc alloy layer is in an amount of less than or equal to 75% to greater than or equal to 25%; or copper in an amount of greater than or equal to 30% to less than or equal to 70%, and the zinc of the copper-zinc alloy layer is in an amount of less than or equal to 70% to greater than or equal to 30%; or copper in an amount of greater than or equal to 35% to less than or equal to 65%, and the zinc of the copper-zinc alloy layer is in an amount of less than or equal to 65% to greater than or equal to 35%; or copper in an amount of greater than or equal to 40% to less than or equal to 60%, and the zinc of the copper-zinc alloy layer is in an amount of less than or equal to 60% to greater than or equal to 40%; or copper in an amount of greater than or equal to 45% to less than or equal to 55%, and the zinc of the copper-zinc alloy layer is in an amount of less than or equal to 55% to greater than or equal to 45%; or copper in an amount of greater than or equal to 45% to less than or equal to 50%, and the zinc of the copper-zinc alloy layer is in an amount of less than or equal to 50% to greater than or equal to 45%.

In a specific example of the present invention, the copper-zinc alloy layer has a thickness of 0.5 μm to 2.5 μm, or 1.0 μm to 2.0 μm, or 1.5 μm to 2.0 μm.

In a specific example of the present invention, the material of the dielectric layer is titanium nitride, zirconium nitride or a combination thereof. In the present invention, the dielectric layer has thermal conductivity and infrared shielding capacity, and can protect the copper-zinc alloy layer from oxidation.

In a specific example of the present invention, the dielectric layer can be plated on the copper-zinc alloy layer by a method selected from vacuum sputtering, but not limited thereto.

In a specific example of the present invention, the dielectric layer has a thickness of 50 nm to 950 nm, or 100 nm to 900 nm, or 150 nm to 850 nm, or 200 nm to 800 nm, or 250 nm to 750 nm, or 300 nm to 700 nm, or 350 nm to 650 nm, or 400 nm to 600 nm, or 450 nm to 550 nm, or 500 nm to 550 nm.

In a specific example of the present invention, the copper-zinc alloy layer and the dielectric layer have a thickness ratio of 5:1 to 95:1, or 10:1 to 90:1, or 15:1 to 85:1, or 20:1 to 80:1, or 25:1 to 75:1, or 30:1 to 70:1, or 35:1 to 65:1, or 40:1 to 60:1, or 45:1 to 55:1, or 50:1 to 55:1. The control for both the thickness and thickness ratio of the copper-zinc alloy layer and the dielectric layer facilitates adjustment of the visibility and thermal conductivity of the heat-resistant protective shield.

In a specific example of the present invention, the heat-resistant protective shield further comprises a primer layer, wherein the primer layer can be formed between the surface of the polycarbonate molded object and the silicon dioxide hard coating to improve the adhesion of the silicon dioxide hard coating to the polycarbonate molded object.

In a specific example of the present invention, the material of the primer layer can be a polyurethane resin or an acrylic resin. In a specific example of the present invention, the material of the primer layer can be a solvent-based material or a water-based material. In a specific example of the present invention, the material of the primer layer is purchased from Eternal Materials (Taiwan) comprising SO-GEL inorganic sol and acrylic resin as main ingredients.

In a specific example of the present invention, the material of the primer layer has a glass transition temperature (Tg) of 70° C. to 120° C., or 80° C. to 110° C., or 90° C. to 100° C.

In a specific example of the present invention, the material of the primer layer has a solid content of 0% to 100%, or 10% to 90%, or 20% to 80%, or 30% to 70%, or 40% to 60%, or 50% to 60%.

In a specific example of the present invention, the heat-resistant protective shield has good heat resistance, wherein the melting temperature thereof is 150° C. or more, 160° C. or more, 170° C. or more, 180° C. or more, 190° C. or more, 200° C. or more, 210° C. or more, 220° C. or more, or 230° C. or more.

In the present invention, an endurance test for the parameters such as infrared light transmittance and visible light transmittance is carried out under the conditions comprising heat treatment at a temperature of 60° C. and a relative humidity of 90RH % for 200 hours; after that, the infrared light transmittance and the visible light transmittance before and after said endurance test are measured to calculate the stability thereof.

In a specific example of the present invention, the heat-resistant protective shield has an infrared light transmittance of 0.6% to 20%, or 0.6% to 18%, or 0.6% to 15%, or 0.6% to 10%, or 0.6% to 5%, or 0.6% to 2.5%, which complies with EN 169 safety standard and/or EN 171 safety standard. In the present invention, the infrared light refers to light with a wavelength of 760 nm to 1 mm, or 780 nm to 2000 nm, or 780 nm to 1400 nm. An excessive high value of the infrared light transmittance of the heat-resistant protective shield indicates a bad shielding capacity which cannot provide effective protection for the operator's face or eyes from the harms resulting from high exposure of infrared light.

In a specific example of the present invention, after the heat-resistant protective shield is heat treated at a temperature of 60° C. and a relative humidity of 90RH % for 200 hours, the heat-resistant protective shield has a change rate of infrared light transmittance of less than 100%, or less than 75%, or less than 50%, or less than 45%, or less than 40%, or less than 30%, or less than 20%, or less than 15%, or less than 10%.

In a specific example of the present invention, the heat-resistant protective shield has a visible light transmittance of 2.5% to 50%, or 2.5% to 40%, or 2.5% to 30%, or 2.5% to 20%, or 2.5% to 10%, or 2.5% to 7%, or 2.5% to 6%, or 2.5% to 5%, which complies with EN 169 safety standard and/or EN 171 safety standard. A heat-resistant protective shield with excessive low visible light transmittance cannot be used as a mask or a goggle; whereas a heat-resistant protective shield with excessive high visible light transmittance hardly provides protection effects.

In a specific example of the present invention, after the heat-resistant protective shield is heat treated at a temperature of 60° C. and a relative humidity of 90RH % for 200 hours, the heat-resistant protective shield has a change rate of the visible light transmittance of less than 100%, or less than 70%, or less than 40%, or less than 30%, or less than 20%, or less than 10%.

In a specific example of the present invention, the endurance test May further comprise a step of illuminating the heat-resistant protective shield with a UV lamp of 500 watts (W) for 200 hours.

In a specific example of the present invention, the polycarbonate molded object is a lens or a face shield.

The heat-resistant protective shield of the present invention has a copper-zinc alloy layer and a dielectric layer, wherein the copper-zinc alloy layer can greatly reduce manufacturing costs, and the dielectric layer can protect the copper-zinc alloy layer from oxidation. The heat-resistant protective shield as a whole has good heat resistance (with a melting temperature of more than 150° C.), good infrared light transmittance (of 0.6% to 20%) and good visible light transmittance (of 2.5% to 50%) and is suitable for serving as a protective mask. Further, the heat-resistant protective shield can withstand an operating temperature of 40° C. to 250° C., and has a low change rate of less than 100% for both the infrared light transmittance and the visible light transmittance after being heat treated at a temperature of 60° C. and a relative humidity of 90RH % for 200 hours, indicating a relatively good stability to maintain good infrared light shielding capacity and good visibility for long term use in high-temperature working environment.

### BRIEF DESCRIPTION OF THE DRAWINGS

FIG. 1 is a side view diagram of the heat-resistant protective shield of the present invention.

FIG. 2A is the infrared light transmission spectrum of the heat-resistant protective shield of Example 1 (E1) after the endurance test.

FIG. 2B is the infrared light transmission spectrum of the heat-resistant protective shield of Example 2 (E2) after the endurance test.

FIG. 2C is the infrared light transmission spectrum of the heat-resistant protective shield of Comparative example 1 (C1) after the endurance test.

FIG. 3A is the photo of the heat-resistant protective shield of C1 after the endurance test.

FIG. 3B is the photo of the heat-resistant protective shield of E1 after the endurance test.

FIG. 3C is the photo of the heat-resistant protective shield of E2 after the endurance test.

### DETAILED DESCRIPTION OF THE PREFERRED EMBODIMENTS

Through the detailed descriptions of the following embodiments and accompanied Figures, the objectives, advantages and technical features of the present invention shall become apparent.

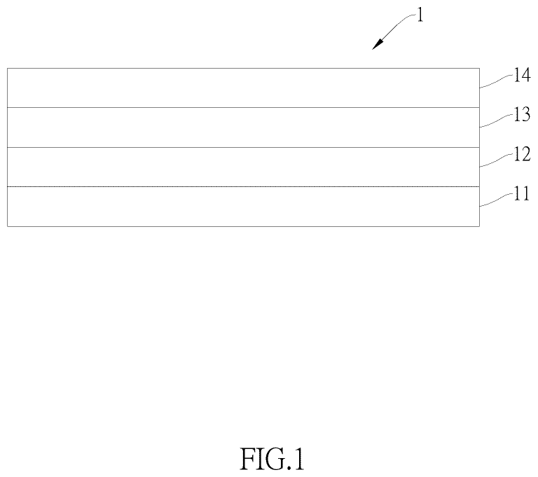

As shown in FIG. 1, a heat-resistant protective shield 1 of the present invention comprises: a polycarbonate molded object 11, a silicon dioxide hard coating 12, a copper-zinc alloy layer 13 and a dielectric layer 14.

### The Preparation of the Heat-Resistant Protective Shield of the Present Invention

First, a polycarbonate molded object, which was a transparent mask that can cover a human face, was provided. A material of a silicon dioxide hard coating, which comprised silica (SiO₂) microparticles, a curing polymer and an oligomer, was applied to a surface of the polycarbonate molded object and then cured to form the silicon dioxide hard coating with a thickness of 4±1 μm.

According to the material of a copper-zinc alloy layer as shown in Tables 1 and 2, a copper-zinc alloy layer was sputtered on the silicon dioxide hard coating by a vacuum sputtering method. Examples 1 to 6 (E1-E6) and Comparative examples 1 to 4 (C1-C4) were sputtered with a copper-zinc alloy layer, wherein the atomic percent (at %) of copper and zinc and the thickness of the copper-zinc alloy layer were shown in Tables 1 and 2. Comparative example 5 (C5) had no copper-zinc alloy layer. Comparative examples 6 and 7 (C6-C7) were sputtered with a conventional material of gold (pure gold).

According to the material of a dielectric layer as shown in Tables 1 and 2, a dielectric layer was sputtered on the copper-zinc alloy layer in Examples 1 to 6 (E1-E6) by a vacuum sputtering method. Comparative examples 1 to 7 (C1-C7) had no dielectric layer. At this point, all the heat-resistant protective shields of each Example and Comparative examples (also abbreviated as “the masks of all groups” hereinafter) were obtained.

### Heat Resistance Test

The masks of all groups were put in an oven, and the temperature was gradually increased to 230° C. By visual observation, the temperatures resulting in melted blisters on the mask were recorded. If no melted blisters were observed at 230° C., the temperature was recorded as above 230° C. (>230° C.). The results were shown in Tables 1 and 2.

### Endurance Test

An endurance test was carried out for the masks of all groups to evaluate the changes of both the visible light transmittance and the infrared light transmittance before and after a long-term use in a high-temperature environment. The endurance test followed ISO4892-2 under a stricter condition as follows. First, illuminate the masks of all groups by a UV lamp (a xenon lamp of 500 W, brand: USHIO, model: UXL-450SP) with an illumination of 13,000 lumens (lm) for 200 hours. Then, put the masks of all groups in an incubator (brand: Giant Force, Model: GTH-408-SSP-SD) at a high temperature of 60° C. and a relative humidity of 90RH % for 200 hours. The infrared light transmittance and the visible light transmittance of the masks of all groups before and after the endurance test were measured to calculate the change rate of the infrared light transmittance and the visible light transmittance.

### Visible Light Transmittance Test

The visible light transmittance of the masks of all groups before and after the endurance test was measured by a spectrometer (brand: HITACHI, model: UH-4150, built-in software: Sunglasses Certification) to calculate the change rate according to the following equation. The results were shown in Tables 1 and 2.

$$The change rate of the visible light transmittance ( \% ) = [ ( the visible light transmittance after the endurance test - the visible light transmittance before the endurance test ) / ( the visible light transmittance before the endurance test ) ] \times 100 \%$$

### Infrared Light Transmittance Test

The infrared light transmittance of the masks of all groups before and after the endurance test was measured by a spectrometer (brand: HITACHI, model: UH-4150, built-in software: Sunglasses Certification) to calculate the change rate according to the following equation. The results were shown in Tables 1 and 2.

The change rate of the infrared light transmittance (%)=[(the infrared light transmittance after the endurance test−the infrared light transmittance before the endurance test)/(the infrared light transmittance before the endurance test)]×100%

According to Tables 1 and 2, Comparative examples 1 to 4 (C1-C4) used copper-zinc alloy to form a copper-zinc alloy layer, but they lacked protection from the dielectric layer, so they had a relatively high infrared light transmittance and visible light transmittance after the endurance test, such as Comparative example 2 (C2); that is, a higher ratio of visible light and infrared light was allowed to penetrate the heat-resistant protective shield of C2. Besides, although the infrared light transmittance and visible light transmittance of C1-C4 fell within a safe range, some comparative examples, such as C1, C3 and C4, had a higher change rate of the infrared light transmittance and visible light transmittance before and after the endurance test, thereby indicating that the heat-resistant protective shields of C1, C3 and C4 had inferior stability and would lose infrared light shielding capacity after a long-term use in a high-temperature environment. Further, Comparative example 5 (C5), which had neither copper-zinc alloy layer nor dielectric layer, melted and blisters occurred at 140° C., that is, C5 had a significantly lower heat resistance. Comparative examples 6 and 7 (C6-C7), which used the conventional material of gold to substitute the material of the copper-zinc alloy layer of the present invention and had no dielectric layer, demonstrated desired results, but they required a significantly higher cost.

Further, the oxidation condition of the copper-zinc alloy layer of the heat-resistant protective shields of Examples 1 and 2 (E1, E2) and Comparative example 1 (C1) was observed.

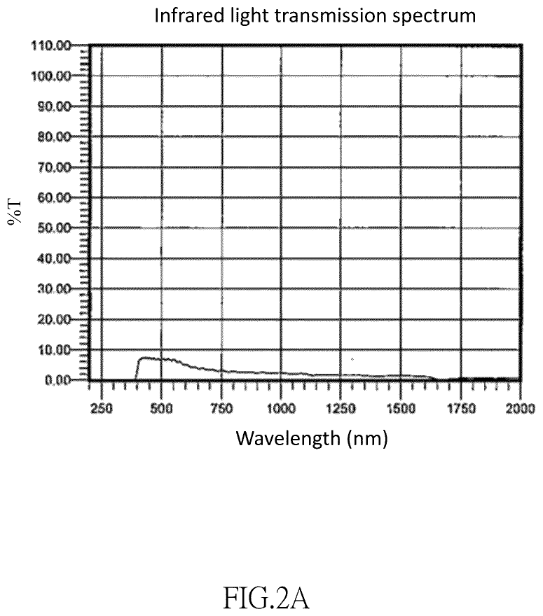

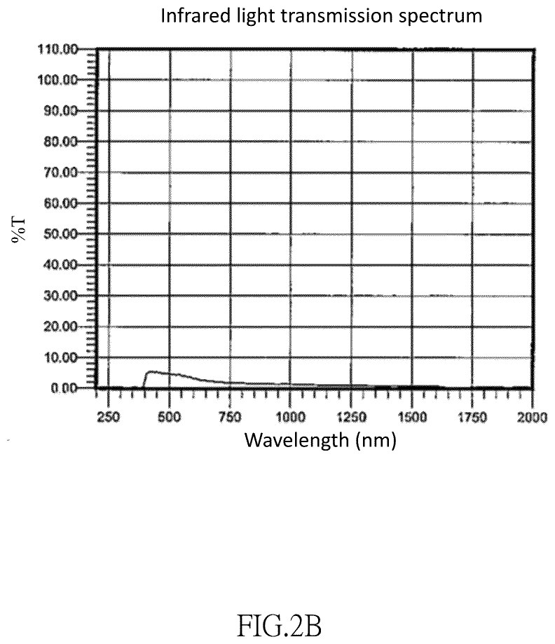

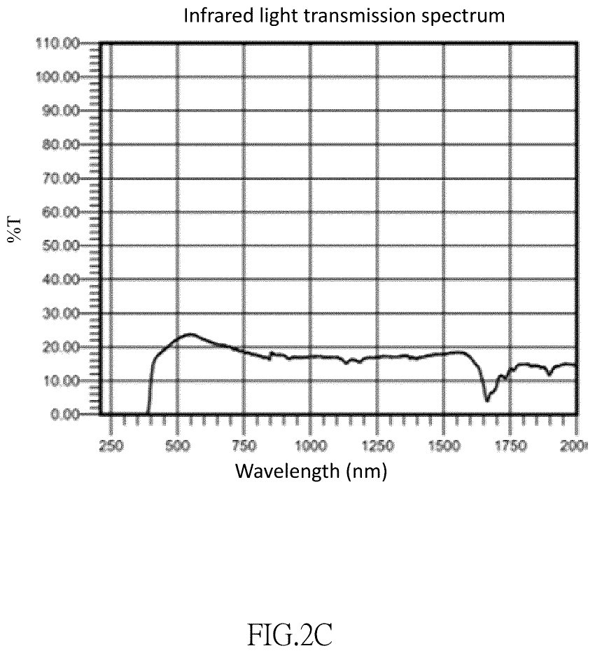

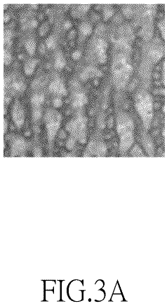

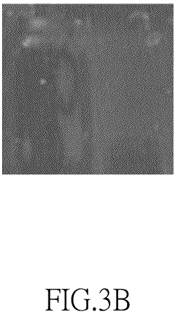

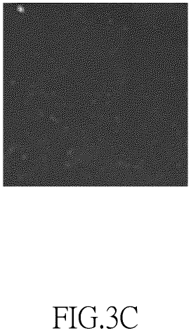

The infrared light transmission spectra of Examples 1 and 2 (E1, E2) and Comparative example 1 (C1) were respectively shown in FIGS. 2A to 2C. Further, the heat-resistant protective shield of Comparative example 1 (C1) and Examples 1 and 2 (E1, E2) after the endurance test were photographed and the photos were shown in FIGS. 3A to 3C. According to FIGS. 2A to 2C and FIGS. 3A to 3C, it was found that Comparative example 1 (C1) had no dielectric layer, and the copper in the copper-zinc alloy layer thereof was significantly oxidized; whereas Examples 1 and 2 (E1, E2), which had the dielectric layer, had no such oxidation occurring and complied with 3M specification requirements.

From above, the heat-resistant protective shield of the present invention uses a copper-zinc alloy layer formed by a copper-zinc alloy and a dielectric layer to substitute the conventional pure gold coating membrane, thereby lowering manufacturing cost. The heat-resistant protective shield as a whole has good heat resistance, good infrared light transmittance and good visible light transmittance, and is suitable for serving as a protective gear for humans. The dielectric layer in the heat-resistant protective shield not only facilitates heat conduction and shields off infrared light, but also protects the copper-zinc alloy layer from oxidation. Further, the heat-resistant protective shield can withstand an operating temperature of 40° C. to 250° C., and it also has a low change rate for both the infrared light transmittance and the visible light transmittance before and after heat treatment at a temperature of 60° C. and a relative humidity of 90RH % for 200 hours, indicating a relatively good stability. Therefore, the heat-resistant protective shield of the present invention is suitable for long term use.

TABLE 1
The material and the data of heat resistance, visible light transmittance
and infrared light transmittance of Examples 1 to 6 (E1-E6)

| | | E1 | | E2 | | E3 | | E4 | | E5 | | E6 | |
|---|---|---|---|---|---|---|---|---|---|---|---|---|---|
| Copper-zinc | Material | Cu | Zn | Cu | Zn | Cu | Zn | Cu | Zn | Cu | Zn | Cu | Zn |
| alloy layer | Ratio (at %) | 85 | 15 | 85 | 15 | 70 | 30 | 60 | 40 | 85 | 15 | 85 | 15 |

| | | | | | | | |
|---|---|---|---|---|---|---|---|
| | Thickness (μm) | 70 ± 10% | 70 ± 10% | 70 ± 10% | 70 ± 10% | 40 ± 10% | 70 ± 10% |
| Dielectric | Material | TiN | TiN | TiN | TiN | TiN | ZrN |
| layer | Thickness (nm) | 20 | 30 | 20 | 20 | 20 | 35 |
| Heat | Melting temperature | >230 | >230 | About 185 | About 168 | About 220 | 210 to 220 |
| resistance | (° C.) | | | | | | |
| Visible light | Before endurance test | 4.30% | 3.3% | 2.1% | 1.8% | 41.1% | 1.4% |
| transmittance | After endurance test | 5.8% | 3.7% | 3.1% | 2.9% | 44.2% | 2.8% |
| | Change rate | 34.88% | 12.12% | 47.62% | 61.11% | 7.54% | 100.00% |
| Infrared light | Before endurance test | 0.46% | 0.86% | 1.3% | 2.6% | 16.9% | 0.64% |
| transmittance | After endurance test | 0.65% | 0.95% | 1.8% | 3.1% | 17.8% | 0.88% |
| | Change rate | 41.30% | 10.47% | 38.46% | 19.23% | 5.33% | 37.50% |

TABLE 2
The material and the data of heat resistance, visible light transmittance
and infrared light transmittance of Comparative examples 1 to 7 (C1-C7)

| | | C1 | | C2 | | C3 | | C4 | | C5 | C6 | C7 |
|---|---|---|---|---|---|---|---|---|---|---|---|---|
| Copper-zinc | Material | Cu | Zn | Cu | Zn | Cu | Zn | Cu | Zn | N/A | Au | Au |
| alloy layer | Ratio (at %) | 85 | 15 | 85 | 15 | 70 | 30 | 60 | 40 | | | |

| | | | | | | | | |
|---|---|---|---|---|---|---|---|---|
| | Thickness (μm) | 70 ± 10% | 40 ± 10% | 70 ± 10% | 70 ± 10% | N/A | 150 ± 10% | 120 ± 10% |
| Dielectric | Material | N/A | N/A | N/A | N/A | N/A | N/A | N/A |
| layer | Thickness (nm) | N/A | N/A | N/A | N/A | N/A | N/A | N/A |
| Heat | Melting temperature | >230 | About 220 | About 190 | About 180 | About | >230 | >230 |
| resistance | (° C.) | | | | | 140 | | |
| Visible light | Before endurance test | 1.2% | 48% | 3.2% | 3.9% | 5% | 4.3% | 48.2% |
| transmittance | After endurance test | 7.6% | 66% | 10.7% | 11.8% | 5% | 5.7% | 52% |
| | Change rate | 533.33% | 37.50% | 234.38% | 202.56% | 0.00% | 32.56% | 7.88% |
| Infrared light | Before endurance test | 0.18% | 18.1% | 1.6% | 2.7% | 75% | 0.4% | 16.3% |
| transmittance | After endurance test | 6.5% | 48.1% | 11.2% | 12.1% | 75% | 0.48% | 17% |
| | Change rate | 3511.11% | 165.75% | 600.00% | 348.15% | 0.00% | 20.00% | 4.29% |

What is claimed is:

1. A heat-resistant protective shield, comprising:
a polycarbonate molded object;
a silicon dioxide hard coating, located on a surface of the polycarbonate molded object;
a copper-zinc alloy layer, located on the silicon dioxide hard coating, the copper-zinc alloy layer having copper in an amount of greater than 0% to less than 100%, and zinc in an amount of less than 100% to greater than 0%; and
a dielectric layer, located on the copper-zinc alloy layer and comprising titanium nitride, zirconium nitride, zirconium dioxide or a combination thereof;
wherein the copper-zinc alloy layer has a thickness of 0.2 micrometers (μm) to 3.0 μm, the dielectric layer has a thickness of 10 nanometers (nm) to 999 nm, and the copper-zinc alloy layer and the dielectric layer have a thickness ratio of 1:1 to 100:1.

2. The heat-resistant protective shield as claimed in claim 1, wherein the cooper of the copper-zinc alloy layer is in an amount of greater than or equal to 30% to less than or equal to 70%, and the zinc of the copper-zinc alloy layer is in an amount of less than or equal to 70% to greater than or equal to 30%.

3. The heat-resistant protective shield as claimed in claim 1, wherein the heat-resistant protective shield has a melting temperature of 150° C. or more.

4. The heat-resistant protective shield as claimed in claim 1, wherein the cooper of the copper-zinc alloy layer is in an amount of greater than or equal to 5% to less than or equal to 95%, and the zinc of the copper-zinc alloy layer is in an amount of less than or equal to 95% to greater than or equal to 5%.

5. The heat-resistant protective shield as claimed in claim 1, wherein the copper-zinc alloy layer and the dielectric layer have a thickness ratio of 1:5 to 1:95.

6. The heat-resistant protective shield as claimed in claim 1, further comprising a primer layer located between the surface of the polycarbonate molded object and the silicon dioxide hard coating.

7. The heat-resistant protective shield as claimed in claim 6, wherein the primer layer is made of a polyurethane resin or an acrylic resin.

8. The heat-resistant protective shield as claimed in claim 1, wherein the heat-resistant protective shield has a visible light transmittance of 2.5% to 50%.

9. The heat-resistant protective shield as claimed in claim 6, wherein the heat-resistant protective shield has a visible light transmittance of 2.5% to 50%.

10. The heat-resistant protective shield as claimed in claim 1, wherein after the heat-resistant protective shield is heat treated at a temperature of 60° C. and a relative humidity of 90RH % for 200 hours, the heat-resistant protective shield has a change rate of a visible light transmittance of less than or equal to 100%.

11. The heat-resistant protective shield as claimed in claim 6, wherein after the heat-resistant protective shield is heat treated at a temperature of 60° C. and a relative humidity of 90RH % for 200 hours, the heat-resistant protective shield has a change rate of a visible light transmittance of less than or equal to 100%.

12. The heat-resistant protective shield as claimed in claim 1, wherein the heat-resistant protective shield has an infrared light transmittance of 0.6% to 20%.

13. The heat-resistant protective shield as claimed in claim 6, wherein the heat-resistant protective shield has an infrared light transmittance of 0.6% to 20%.

14. The heat-resistant protective shield as claimed in claim 1, wherein after the heat-resistant protective shield is heat treated at a temperature of 60° C. and a relative humidity of 90RH % for 200 hours, the heat-resistant protective shield has a change rate of infrared light transmittance of less than or equal to 100%.

15. The heat-resistant protective shield as claimed in claim 6, wherein after the heat-resistant protective shield is heat treated at a temperature of 60° C. and a relative humidity of 90RH % for 200 hours, the heat-resistant protective shield has a change rate of infrared light transmittance of less than or equal to 100%.

16. The heat-resistant protective shield as claimed in claim 1, wherein the polycarbonate molded object is a lens or a face shield.

17. The heat-resistant protective shield as claimed in claim 6, wherein the polycarbonate molded object is a lens or a face shield.
